(19) United States
(12) Patent Application Publication
(10) Pub. No.: US 2016/0126169 A1
(43) Pub. Date: May 5, 2016

(54) LEADLESS SEMICONDUCTOR DEVICE AND METHOD OF MAKING THEREOF

(71) Applicant: NXP B.V., Eindhoven (NL)

(72) Inventors: Chi Ho Leung, Kwun Tong (HK); Yee Wai Fung, Kwai Chung (HK); WaiKeung Ho, Kwai Chung (HK)

(21) Appl. No.: 14/527,302

(22) Filed: Oct. 29, 2014

(51) Int. Cl. H01L 23/495; H01L 21/56

(52) U.S. Cl. CPC H01L 23/49575; H01L 21/56

(57) ABSTRACT

Consistent with an example embodiment, there is a leadless packaged semiconductor device having top and bottom opposing major surfaces and sidewalls extending there between. The leadless packaged semiconductor device comprises a lead frame sub-assembly having an array of two or more lead frame portions each having a semiconductor die arranged thereon. At least five I/O terminals each of said terminals comprise a respective metal side pad; and the respective metal side pad has a step profile. A feature of this embodiment is that these metal side pads, having a step profile, are electroplated to enhance their solderability.

### FIELD

This disclosure relates to integrated circuit (IC) packaging. More particularly, this disclosure relates to a leadless packaged semiconductor device and a method of making thereof.

### BACKGROUND

The electronics industry continues to rely upon advances in semiconductor technologies to realize higher-function devices in more compact areas. For many applications realizing higher-functioning devices requires integrating a large number of electronic devices into a single silicon wafer. As the number of devices per given area of the silicon wafer increases, the manufacturing process becomes more difficult.

Many varieties of semiconductor devices have been manufactured having various applications in numerous disciplines. Such silicon-based semiconductor devices often include metal-oxide-semiconductor field-effect transistors (MOSFET), such as p-channel MOS (PMOS), n-channel MOS (NMOS) and complementary MOS (CMOS) transistors, bipolar transistors, BiCMOS transistors. Such MOSFET devices include an insulating material between a conductive gate and silicon-like substrate; therefore, these devices are generally referred to as IGFETs (insulated-gate FET).

Having manufactured a number of electronic devices on a wafer substrate, a particular challenge is to package these devices for their given purpose. As the complexity of portable systems increases, there is a commensurate need to reduce the size, enhance the electrical performance, and enhance the thermal performance of the individual components which make up the system as the device often is laid out on a printed circuit substrate. There is a need for packaging which can address these challenges.

### SUMMARY

In an example embodiment, there is a leadless packaged semiconductor device having top and bottom opposing major surfaces and sidewalls extending there between. The leadless packaged semiconductor device comprises a lead frame sub-assembly having an array of two or more lead frame portions each having a semiconductor die arranged thereon. At least five I/O terminals each of said terminals comprise a respective metal side pad; and the respective metal side pad has a step profile. A feature of this embodiment is that these metal side pads having a step profile are electroplated to enhance their solderability.

In another example embodiment, there is a method for forming a semiconductor device in a leadless chip carrier (LCC) having a lead frame assembly having an array of sub-assemblies each having a device die arranged thereon, the sub-assemblies having I/O terminals electrically connected to the device die, and the I/O terminals mutually connected by a connection bar. The method comprises encapsulating the lead frame assembly and the I/O terminals in a molding compound. In a first direction in a series of parallel cuts is made. A laser cuts the molding compound covering the I/O terminals, to a depth of the connection bar, exposing vertical surfaces and horizontal surfaces of the I/O terminals. Electroplating the I/O terminals to forms plated vertical and horizontal surfaces. An additional series of cuts is performed by cutting in the first direction extending through the connection bars and the molding compound, thereby forming a plated step profile on the I/O terminals. In a second direction in a series of parallel cuts with the second direction angled with respect to the first direction, the second series of cuts extends through the lead frame assembly and molding compound to singulate an individual device from the lead frame assembly.

The above summaries of the present invention are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIGS. 1A-1E are simplified cross-sectional views of the making of a device according to an embodiment of the present disclosure;

FIGS. 2A-2B are underside views of an example lead frame that may be used in assembling a device according to an embodiment of the present disclosure;

FIGS. 3A-3B are perspective underside views of an example lead frame in which a device has been assembled according to an embodiment of the present disclosure;

FIGS. 4A-4B are scanning electron micrographs (SEM) of a device assembled according to the present disclosure

FIG. 5 is a flow diagram of an assembly process according to an embodiment of the present disclosure; and

FIGS. 6A-6B illustrate a device die assembled according to the present disclosure and one not.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present disclosure has been found useful in addressing the challenges packaging of semiconductor devices used in portable systems. Leadless packaged semiconductor devices are known to provide advantages over leaded packages. Those advantages include better electrical performance in terms of reduced lead inductance, good heat dissipation by use of an exposed thermal pad to improve heat transfer to a PCB (printed circuit board), reduced package thickness and smaller footprint, which reduces the area occupied on a PCB. Examples of leadless packaged semiconductor devices include QFN (quad-flat no-lead devices) and DFN (discrete-flat no-lead devices). However, a disadvantage of leadless packaged semiconductor devices is that inspection of solder joints when mounted on a PCB can be difficult. Conventional inspection techniques utilize so-called Automated Optical Inspection (AOI) systems, whereby a camera scans the leadless packaged semiconductor devices mounted on the PCB for a variety of defects such as open circuit connections, short circuit connections, thinning of the solder connections and incorrectly placed devices. Due to the semiconductor device I/O terminals being arranged on the bottom of the device, and therefore hidden from view when the device is mounted a PCB, it is not generally possible to use AOI systems with leadless semiconductor devices. Automatic X-Ray Inspection (AXI) systems may allow inspection of solder joints, however AXI systems are expensive.

A solution allowing solder joints to be inspected by AOI is to include a metal side pads which extend from the device I/O terminals on the bottom of the device at least partially up external sidewall of the device. Typically the metal side pads may be formed of tin, lead or tin-lead alloys. During soldering processes attaching the device to the PCB, the solder will wet the I/O terminal on the bottom of the device and also the metal side pads. As a result a portion of the solder joint will be visible allowing inspection by AOI techniques. The solder joint may be considered good, provided that the metal side pads are correctly soldered even if the I/O terminal is not correctly soldered to the PCB.

In addition to ease of inspection, metal side pads may reduce tilting of the device when mounted on a PCB. Metal side pads may also improve shearing and bending performance because of the increased soldered area.

In an example embodiment, a package structure comprises an array of device dies embedded in an encapsulation layer. The device dies are connected to a lead frame by any appropriate technique, such as eutectic bonds. The process of forming such leadless device involves dividing a two dimensional array of encapsulated integrated circuits into individual semiconductor device packages using a series of parallel row cuts and parallel column cuts. The first series of parallel cuts extend fully through the lead frame and encapsulation layer defining rows of the array.

After electro-plating metal side pads, a second series of parallel cuts is made extending fully through the lead frame and encapsulation layer. This separates the columns of the array thereby providing singulated packages. In such a process the I/O terminals will be exposed and since the I/O terminals are mutually electrically connected the exposed I/O terminals may be electroplated to form the metal side pads. The electrical connection is necessary to maintain electrical continuity so that the electroplating process can be achieved.

However, for leadless semiconductor devices having two separate functional dies and at least three I/O terminals located at one sidewall of the device and at least two I/O terminals located at an opposing sidewall, it may not be possible to form side pads by electroplating according to above process because the cutting sequence requires that middle I/O terminals located at one sidewall of the device formed on a lead frame structure on lead frame be electrically isolated. Some I/O terminals after the first cut become isolated and cannot be electro-plated.

Further, for some leadless packages the number of I/O terminals is limited to three on packages of dimensions less than 1.1 mm×1.1 mm. For other leadless packages, the number of I/O terminals is limited to six for those package sizes larger than 2 mm×2 mm.

Consistent with an example embodiment, there is a method that may be applied to leadless packages having side-solderable I/O terminals whose number is not limited. A lead frame assembly has an array of sub-assemblies. Each sub-assembly has die attach regions surrounded by I/O terminals. The I/O terminals and die attach regions of each sub-assembly are electrically and mechanically coupled together with connection bars. During the manufacturing of electronic device, semiconductor device die are die attached onto one side of the lead frame assembly in the array of sub-assemblies. The device die are then wire-bonded to the corresponding I/O terminals. In an example lead frame one of the I/O Terminals is electrically connected to the die attach region to provide connection to the device die underside. Having attached and wire bonded the array of device die, the lead frame assembly is encapsulated into a molding compound.

So that individual devices may be reliably mounted onto a printed circuit board (PCB) sub-system, the exposed I/O terminals have to be plated with a solderable material, such as tin (Sn). Electro-plating this surface has been found useful in achieving a solderable surface on both the exposed underside surfaces of the I/O terminals. However, the quality of the soldering is not visible on mounted products. A challenge is to provide a rapid way of inspecting the solder quality. A challenge is to electroplate the corresponding exposed vertical faces of the I/O terminals. Having the plated vertical face enables one to observe the solder meniscus on the vertical surface; a sufficient meniscus visible on the vertical surface means that the underside soldering is sufficient.

The encapsulated lead frame assembly is exposed to a laser to remove molding compound in connection bar connecting the I/O terminals of each sub-assembly to one another. Exposing the connection bars opens up these vertical surfaces to electroplating, as the lead frame assembly is dipped into an electroplating bath. The laser provides for a smooth vertical profile in the area exposed; such a profile is not attainable with a saw.

After electroplating, the array of assembled and electroplated device die are singulated by sawing. The sawing would be done in the X and Y directions of the connection bars. In that the connection bar in the X-direction was attached to a portion of the vertical face, there is an un-plated portion exposed. The electroplated portion has a step profile. The step profile provides for a containment of the solder meniscus during subsystem assembly. For an example lead frame used, a visual profile of half solder/half copper would indicate a sufficient solder connection was made.

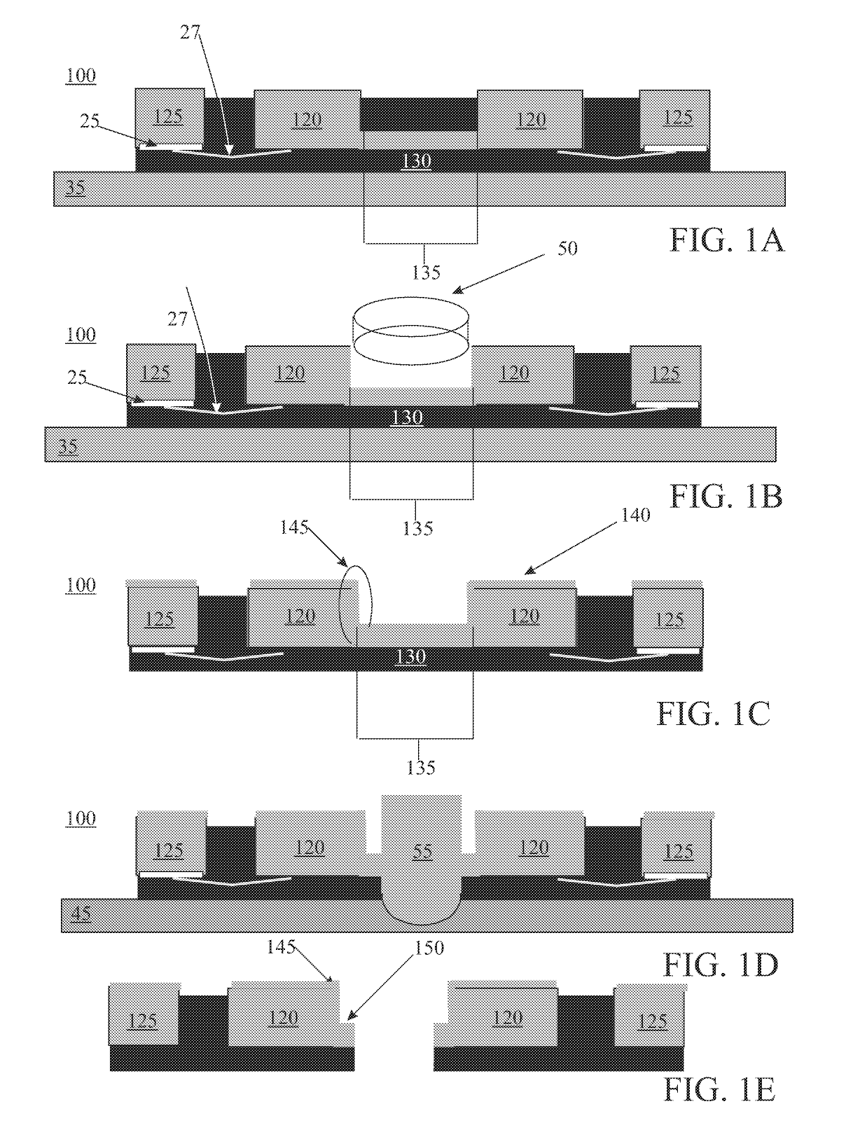

Refer to FIGS. 1A-1E. In an example embodiment, device die 25 are attached to a lead frame assembly 100 on a first side; the lead frame assembly 100 has been mounted onto a carrier tape 35. In an example embodiment, the lead frame assembly 100 may be made of copper or of a copper alloy coated with palladium gold through a photo etching process. Wire bonding 27 connects device 25 I/O pads 120a and 120b to corresponding die attach pads 125a and 125b on the lead frame assembly 100. Molding compound 130 envelopes the wire bonded device die 25 and flows between spaces between the I/O pads 120a, 120b and die attach pads 125a, 125b. A connection bar 135 maintains the mechanical relationship between the die attach pads 125a, 125b and the I/O pads 120a, 120b. Molding compound 130 also envelopes the connection bar 135.

Refer to FIG. 1B. With a laser 45 suitably tuned for etching molding compound. The laser beam 50 etches through the molding compound 130 until the connection bar 130 is exposed. With the carrier tape 35 removed, the exposed connection bar 135, the I/O pads 120a, 120b and the exposed die attach pads 125a, 125b (on an opposite second side) receive an electroplating of a solderable metal 140. Note that the vertical surface 145 of the I/O pads 120a, 120b, once covered by molding compound 130 have been electroplated, as well. Refer to FIG. 1C. Solderable conductive metals may include, but not be limited to, tin (Sn), nickel (Ni), gold (Au), palladium (Pd), or silver (Ag), etc. In some applications, there may be layers of different metals applied in a multiple electroplating process of different electrolytic baths.

After the electroplating, the lead frame assembly 100 is mounted on a second carrier tape 45. Refer to FIGS. 1D-1E. The lead frame assembly 100 is sawed apart about the midpoint of the connection bar 130 with a blade 55 of suitable kerf. After sawing, the electroplated metal 145 has a step 150, owing to the portion of the connection bar 135 that held the lead frame sub-assemblies together at the I/O terminals.

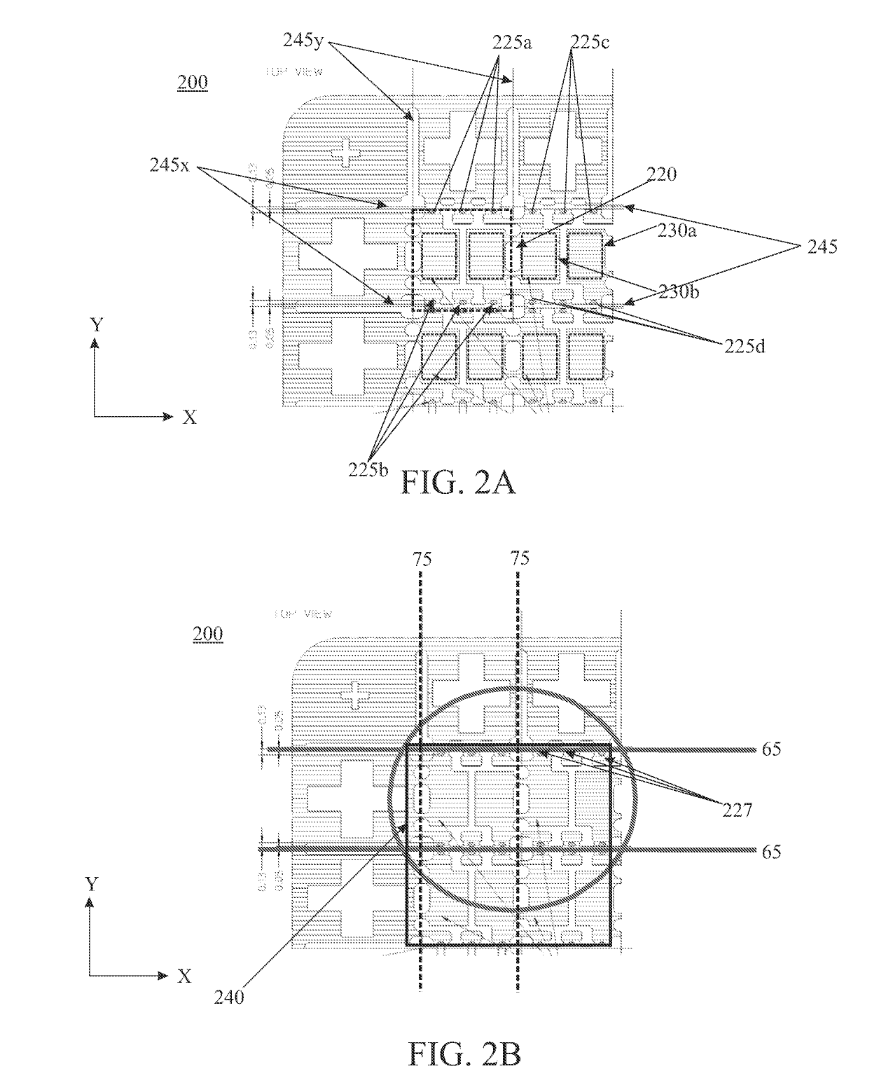

Refer to FIGS. 2A-2B. In an example embodiment, a lead frame assembly 200 has an array of device positions 220. A device position 220 accommodates two device die at die attach areas 230a, 230b. As discussed in connection with FIGS. 1A-1D, the device die are attached to (and wire bonded to) an underside surface of the lead frame assembly 200. Each device die has three I/O terminals 225a, 225b, 225c and 225d. Connection bars 245 (shown by double-lines) provide electrical connection to all the three I/O terminals of each device die so that a solderable surface can be electroplated thereon. The connection bar 245x has stubs 227 which are perpendicular to the vertical faces of the I/O terminals. After encapsulation in molding compound, laser cutting of molding compound, and electroplating, the connection bars 245x are sawed with a blade 65. A second sawing (at connection bars 245y) with a blade 75 singulates the array of device positions 220. Each one of the two sets of I/O terminals 225 are associated with each one of the die attach areas 230 so that appropriate connections can be made to the device die. Some applications requiring two device die may include dual transistor arrangements or dual diode arrangements. Although this example lead frame has two die positions, the present disclosure may apply to lead frame arrays having three or more die attach areas and their corresponding I/O terminals.

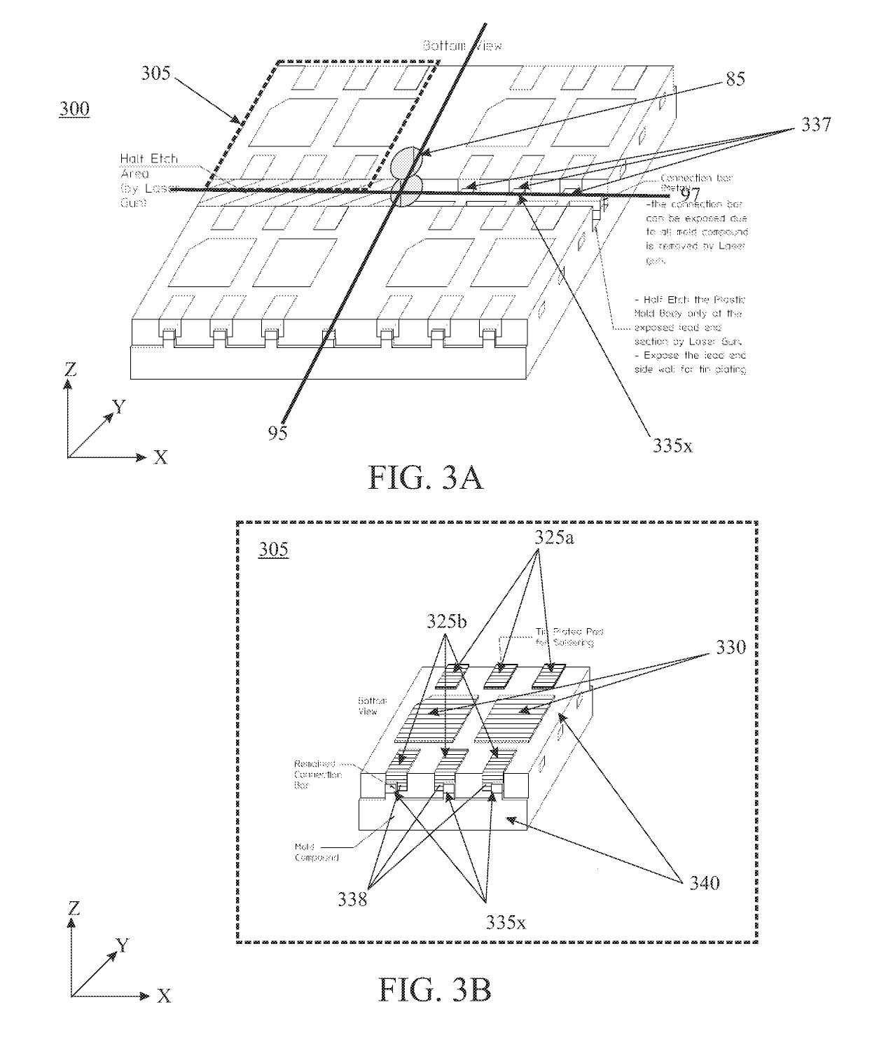

Refer to FIGS. 3A-3B. In perspective views of a portion of an example lead frame assembly 300, having four device positions 305, a laser beam 85 cuts through the molding compound 340 to a depth such that the connection bar 335x is exposed. With the connection bar 335x exposed, the I/O terminals 325a, 325b can undergo electroplating on their horizontal and vertical surfaces. Note that the connection bar 335x has stubs 337 perpendicular to and integrally connected to the I/O terminals. The exposed die-attach areas 330 on the underside of the lead frame assembly 300, receive electroplating, as well. After electroplating, the lead frame of now-electroplated devices 305 may be singulated with a saw cut with a blade 95, in a perpendicular direction to the laser cut 85, followed by a an additional saw cut 97. The saw cut 97 removes only a portion of the stubs 337 from the I/O terminals 325 thereby leaving a stepped profile (from stub remnants 338) on the vertical faces of the I/O terminals. Refer to FIG. 3B. The singulated device 305 has electroplated I/O pads 325a, 325b and electroplated exposed undersides of the die attach pads 335a, 335b.

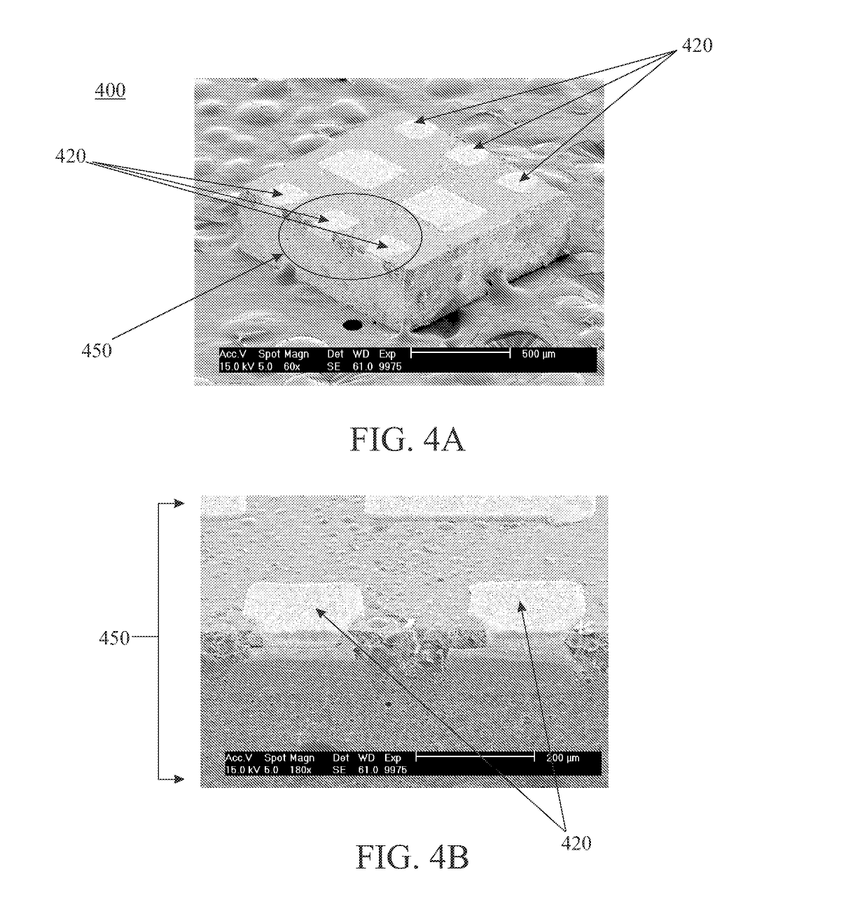

Refer to FIG. 4A. A scanning electron micrograph (SEM) of a packaged device 400 assembled according to the present disclosure shows the I/O terminals 420 plated on their horizontal and vertical surfaces. FIG. 4B is a close-up view 450 of two I/O terminals 420.

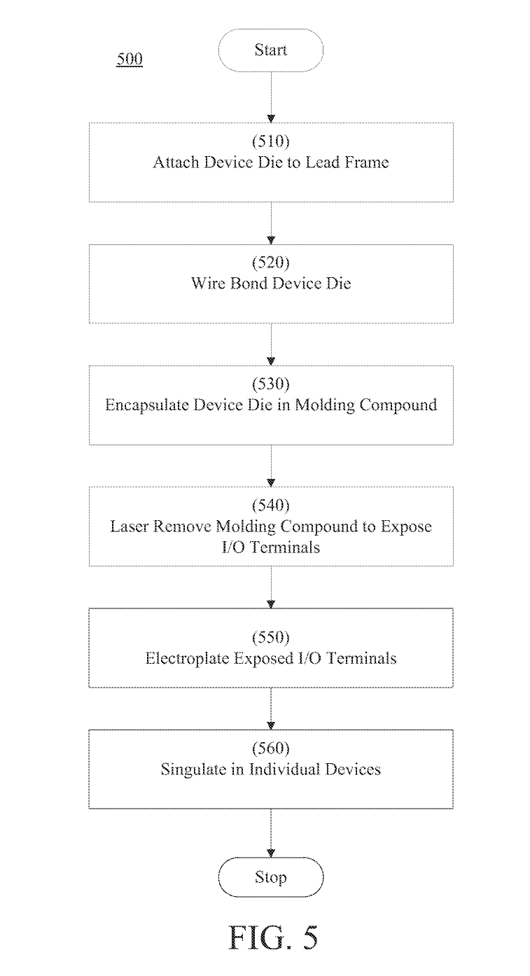

Refer to FIG. 5. A method 500 according to embodiments of the present disclosure assures that horizontal and vertical surfaces of a packaged device's I/O terminals have solderable surfaces thereon. In step 510, after an appropriate lead frame assembly (with an array of device positions) having an underside surface and an opposite topside surface is chosen, device die are attached to an array die attach surfaces on the topside surface of the lead frame. Next, in step 520, the device die are wire bonded to the I/O terminals. In step 530 the wire bonded device die are encapsulated in a molding compound. After encapsulation, in step 540, a laser is used to remove the molding compound to expose the vertical surfaces of the I/O terminals. In that both the vertical and horizontal surfaces of the I/O terminals are exposed, the lead frame having an array of encapsulated device die undergoes electroplating in step 550. The array of packaged and electroplated device die are singulated into individual devices, in step 560. Depending requirements, these individual devices may undergo a final electrical testing and a visual inspection prior to shipping to the end user.

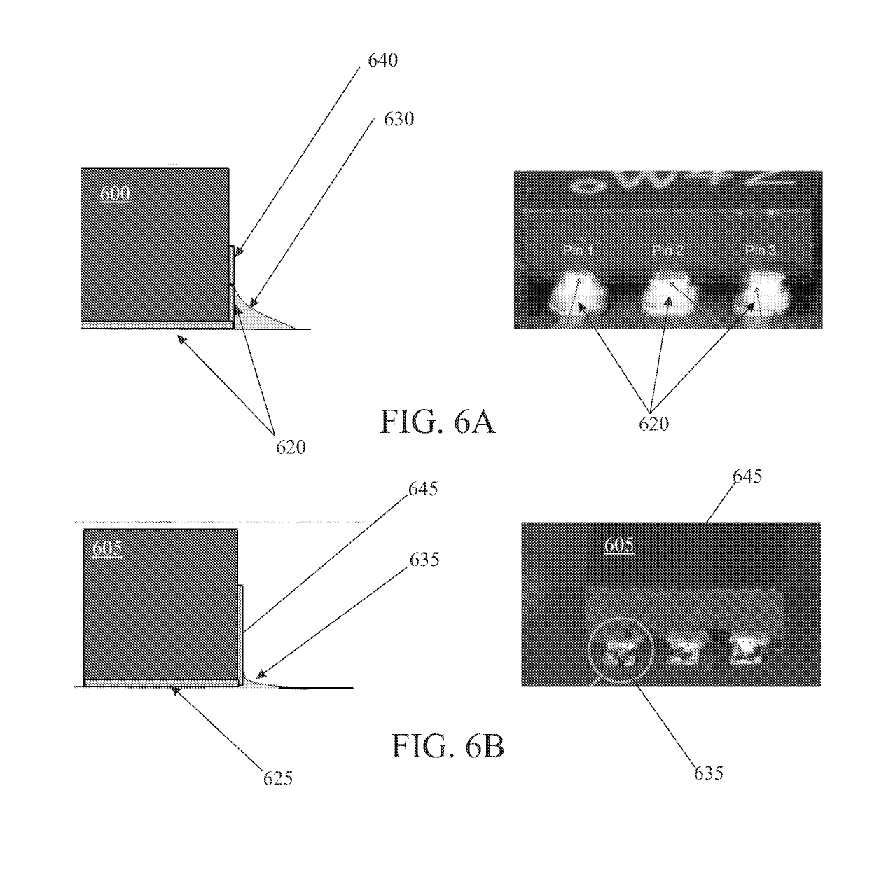

Refer to FIGS. 6A-6B. In FIG. 6A, a device 600 assembled according to the present disclosure has a tin plating 620 on the underside face and substantially on the vertical face of the I/O terminal. The solder 630 wicks up from the underside and forms a meniscus (on the plated regions but not on the un-plated regions 640) which is readily visible through automated optical inspection. In contrast (FIG. 6B), a device 605 whose vertical face of the I/O terminals is un-plated copper 645. The solder 635 cannot form a visible meniscus which is readily visible through automated optical inspection. One cannot ascertain whether the solder join on the underside surface is sufficient without the use of more costly analysis.

While the above discussion relates to leadless packaged semiconductor devices having three or more I/O terminals on each opposing side of the device (that is arranged as a so-called dual in line arrangement), and with two or more electrically isolated die attach regions 230, the process can be used for multiple I/O terminal configurations and multiple electrically isolated die attached regions. The skilled person will appreciate that I/O terminals and die attached regions need to be electrically connected to each other after the first cut, so as to allow for electroplating and then mutually electrically separated so as to allow for correct functioning of the device dies and ultimately the final packaged device.

In another example, the connection bars in both the X and Y directions may be coupled to I/O terminals that surround a die attach regions. These may be LCC packages whose I/O terminals are on all four sides. The laser cutting process would remove molding compound in both the X and Y directions to expose the connection bars for electroplating.

Various exemplary embodiments are described in reference to specific illustrative examples. The illustrative examples are selected to assist a person of ordinary skill in the art to form a clear understanding of, and to practice the various embodiments. However, the scope of systems, structures and devices that may be constructed to have one or more of the embodiments, and the scope of methods that may be implemented according to one or more of the embodiments, are in no way confined to the specific illustrative examples that have been presented. On the contrary, as will be readily recognized by persons of ordinary skill in the relevant arts based on this description, many other configurations, arrangements, and methods according to the various embodiments may be implemented.

To the extent positional designations such as top, bottom, upper, lower have been used in describing this disclosure, it will be appreciated that those designations are given with reference to the corresponding drawings, and that if the orientation of the device changes during manufacturing or operation, other positional relationships may apply instead. As described above, those positional relationships are described for clarity, not limitation.

The present disclosure has been described with respect to particular embodiments and with reference to certain drawings, but the invention is not limited thereto, but rather, is set forth only by the claims. The drawings described are only schematic and are non-limiting. In the drawings, for illustrative purposes, the size of various elements may be exaggerated and not drawn to a particular scale. It is intended that this disclosure encompasses inconsequential variations in the relevant tolerances and properties of components and modes of operation thereof. Imperfect practice of the invention is intended to be covered.

Where the term “comprising” is used in the present description and claims, it does not exclude other elements or steps. Where an indefinite or definite article is used when referring to a singular noun, e.g. “a” “an” or “the”, this includes a plural of that noun unless something otherwise is specifically stated. Hence, the term “comprising” should not be interpreted as being restricted to the items listed thereafter; it does not exclude other elements or steps, and so the scope of the expression “a device comprising items A and B” should not be limited to devices consisting only of components A and B. This expression signifies that, with respect to the present disclosure, the only relevant components of the device are A and B.

Numerous other embodiments of the disclosure will be apparent to persons skilled in the art without departing from the spirit and scope of the disclosure as defined in the appended claims.

1. A method for forming a semiconductor device in a leadless chip carrier (LCC) having a lead frame assembly having an array of sub-assemblies each having a device die arranged thereon, the sub-assemblies having I/O terminals electrically connected to the device die, and the I/O terminals mutually connected by a connection bar, the method comprising:
encapsulating the lead frame assembly and the I/O terminals in a molding compound;
in a first direction in a series of parallel cuts, laser cutting the molding compound covering the I/O terminals, to a depth of the connection bar, exposing vertical surfaces and horizontal surfaces of the I/O terminals;
electroplating the I/O terminals to form plated vertical and horizontal surfaces;
performing an additional series of cuts, cutting in the first direction extending through the connection bars and the molding compound, thereby forming a plated step profile on the I/O terminals; and
in a second direction in a series of parallel cuts, the second direction angled with respect to the first direction, the second series of cuts extending through the lead frame assembly and molding compound to singulate an individual device from the lead frame assembly.

2. The method as recited in claim 1, where in each of the sub-assemblies comprises at least five terminals and wherein at least two I/O terminals are disposed on one side of a lead frame sub-assembly and the remaining I/O terminals are on an opposite side of the lead frame sub-assembly.

3. The method as recited in claim 2, wherein each of lead frame sub-assemblies has at least two separate die attach regions.

4. The method as recited in claim 2, wherein each of the sub-assemblies comprises at least one terminal on each of four sides surrounding the device die arranged thereon.

5. A leadless packaged semiconductor device having top and bottom opposing major surfaces and sidewalls extending there between, the leadless packaged semiconductor device comprising:
a lead frame sub-assembly having an array of two or more lead frame portions each having a semiconductor die arranged thereon;
at least five I/O terminals wherein each of said terminals comprise a respective metal side pad; and
wherein the respective metal side pad has a step profile.

6. The leadless packaged semiconductor device as recited in claim 5, wherein the I/O terminals are disposed on opposing side walls, wherein at least two I/O terminals are disposed on one of said sidewalls and the remaining I/O terminals are disposed on an opposing side wall.

7. The leadless packaged semiconductor device as recited in claim 5, wherein each of the lead frame portions comprise a die attach region including therewith an integrally formed terminal.

8. The leadless package semiconductor device as recited in claim 5 wherein each of two or more lead frame portions are electrically isolated.

9. The leadless package semiconductor device as recited in claim 6, wherein each of metal side pads are electroplated.
